(19) United States
(12) Patent Application Publication
(10) Pub. No.: US 2024/0411457 A1
(43) Pub. Date: Dec. 12, 2024

(54) DATA MIGRATION USING TRANSACTION ORDER IN SOLID STATE DRIVES

(71) Applicant: DELL PRODUCTS L.P., Round Rock, TX (US)

(72) Inventors: Seungmin Oh, Singapore (SG); Young Hwan Jang, Singapore (SG)

(21) Appl. No.: 18/332,167

(22) Filed: Jun. 9, 2023

(51) Int. Cl. G06F 3/06; G06F 12/0802

(52) U.S. Cl. CPC G06F 3/0613; G06F 3/0647; G06F 3/0679; G06F 12/0802; G06F 2212/305

(57) ABSTRACT

An information handling system includes a host system and an SSD. The SSD includes a memory array having memory cells and a controller. The memory array includes a first portion of the memory cells configured to store one bit per cell, and a second portion of the memory cells configured to store more than one bit per cell. The controller utilizes the first portion as a cache for the second portion. The controller utilizes a caching policy based upon a plurality of unique order identifiers, each order identifier being associated with a particular data block stored in the first portion. Each order identification is determined based upon a chronological order in which the associated data is accessed in the first portion.

### FIELD OF THE DISCLOSURE

This disclosure generally relates to information handling systems, and more particularly relates to providing a data migration scheme using transaction order for faster reads in solid state drives (SSDs).

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

An information handling system may include a host system and an SSD. The SSD may include a memory array having memory cells and a controller. The memory array may include a first portion of the memory cells configured to store one bit per cell, and a second portion of the memory cells configured to store more than one bit per cell. The controller may utilize the first portion as a cache for the second portion. The controller may utilize a caching policy based upon a plurality of unique order identifiers, each order identifier being associated with a particular data block stored in the first portion. Each order identification may be determined based upon a chronological order in which the associated data is accessed in the first portion.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIG. 1 is a block diagram of an information handling systems according to an embodiment of the current disclosure;

FIG. 2 illustrates a method for utilizing a single level cell (SLC) segment in the memory storage array of FIG. 1; and

FIG. 3 is a block diagram illustrating a generalized information handling system according to another embodiment of the present disclosure;

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

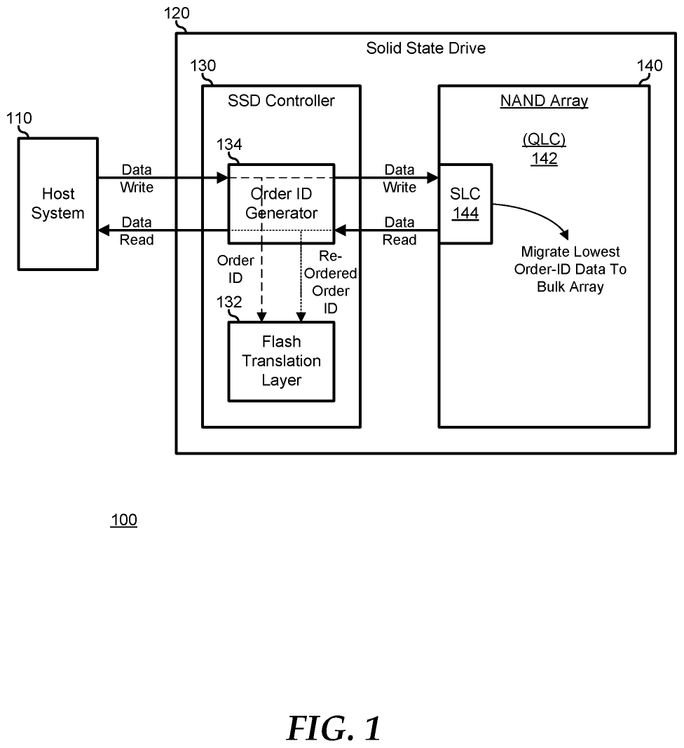

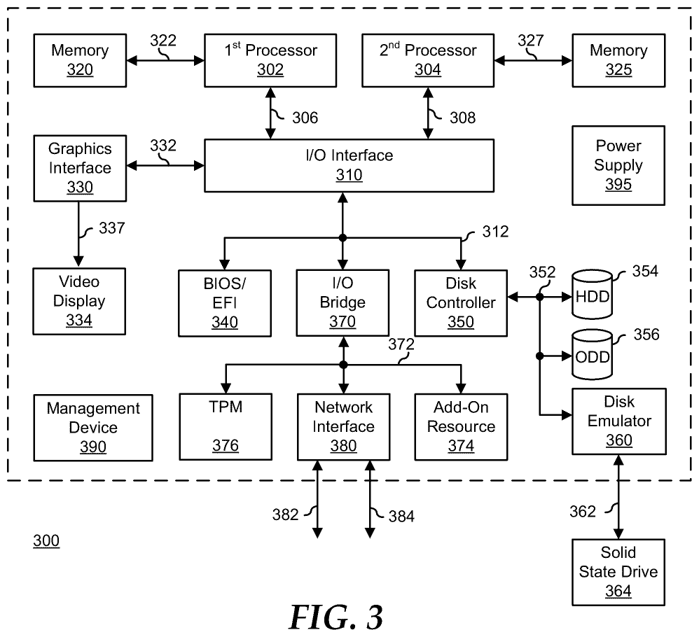

FIG. 1 illustrates an information handling system 100 including a host system 110 and a solid state drive (SSD) 120. Host system 110 represents the functions and features of a computer system, such as the information handling system 300 of FIG. 3, as described below. SSD 120 represents a storage device that provides non-volatile memory storage for information handling system 100, and includes an SSD controller 130 and a memory storage array 140. SSD controllers similar to SSD controller 120, and the functions thereof, are known in the art, and the details of such functions will not be further described herein, except as may be needed to illustrate the current embodiments.

Memory storage array 140 is illustrated as a NAND flash storage array. Here, flash memory is typically operable to provide multiple storage cells that each operate to store one or more bit of data, depending on the particular flash memory technology utilized. For example, a particular flash memory device my operate the storage cells in a single-level mode that stores a single bit per cell (SLC), a multi-level mode that stores two (2) bits per cell (MLC), a tri-level mode that stores three (3) bits per cell (TLC), or a quad-level mode that stores four (4) bits per cell (QLC). operating in the higher level modes (MLC, TLC, and QLC), a flash memory exhibits a higher data storage capacity, but sacrifices other performance metrics.

Such performance metrics are provided for a typical flash memory in Table 1, below. As can be seen, operating in the SLC mode provides the most robust performance, as indicated by the program/erase (P/E) cycles, and the fastest read, program, and erase times. On the other hand, operating in the QLC mode provides for the least robust performance and the slowest read, program, and erase times.

TABLE 1
NAND Cell Performance

| | SLC | | MLC | | TLC | | QLC | |
|---|---|---|---|---|---|---|---|---|
| Bits/Cell | 1 | | 2 | | 3 | | 4 | |
| P/E Cycles | 100,000 | | 10,000 | | 3,000 | | 1,000 | |
| Read Time | 25 | μs | 30 | μs | 30 | μs | >120 | μs |
| Program Time | 200-300 | μs | 300-400 | μs | 500-800 | μs | >3000 | μs |
| Erase Time | 5 | ms | 5 | ms | 8 | ms | >8 | ms |

In order to compensate for the low performance and access times, while still maintaining a large data storage capacity, SSDs typically incorporate a feature where the bulk of the data storage cells of the memory storage array are operated at their highest capacity operating mode (that is, in QLC mode), and where a segment of the data storage cells are operated at their highest performance operating mode (that is, in SLC mode). Thus memory storage array 140 is illustrated where the bulk portion of the memory storage array is operated in the QLC mode (QLC segment 142), and where a smaller segment is operated in the SLC mode (SLC segment 144). In this case, SLC segment 142 is operated as a cache segment to store more frequently used data, while the QLC segment 142 is operated as the bulk storage media. In a particular embodiment, memory storage array 140 has a maximum data storage capacity in the QLC mode of between 512 gigabytes (GB) and four (4) terabytes (TB), and the memory storage array will be configured with a SLC segment 144 of 50-500 GB, but the ratio of the SLC portion to the QLC portion may be up to one quarter (¼) or more, as needed or desired. In the typical SSD, the caching policy and algorithm for evicting data from a SLC portion to a high-capacity portion of the memory storage array may be based upon a determination to evict the most invalid data pages to the high-capacity portion.

It has been understood by the inventors of the current disclosure that the most recently programmed data to an SSD has a higher likelihood of being read back from the SSD than earlier programmed data. As such, in a particular embodiment, SSD 120 operates to provide a caching policy based upon the retention of the most recently programmed data. Such caching policy and algorithm may provide a greater overall performance than can be provided by the typical SSD policy based upon data page validity.

As such, SSD controller 130 includes a flash translation layer table 132 and an order identification (ID) generator 134. Flash translation layer (FTL) table 132 represents a mapping table that is managed by SSD controller 130 to map the logical addresses of data reads and writes to SSD 120 to the physical block locations of the associated data within memory storage array 140. The functions and features of FTL table are known in the art. Thus the features of FTL 132 that relate to the typical functions and features of FTL tables will not be further described herein, except as may be needed to illustrate the current embodiments. In particular, it may be understood that the functions and features of a FTL table similar to FTL table 132 may be instantiated within host system 110, or elsewhere within information handling system 100, without violating the current embodiments.

Order ID generator 134 operates to ascribe a chronological ordering of the data programmed to SSD 120, and to record the ascribed order (the order ID) to the data within FTL table 132. In this way, each entry within FTL table 132 may include a logical address associated with a particular block of data, a logical address at which the data is stored in memory storage array 140, and the ascribed order ID information for the data. As such, FIG. 1 illustrates a data write operation from host system 110 to SSD 120. The data write operation will be understood to include a data block and a logical address associated with the data block. Order ID generator 134 receives the data write, and ascribes an order ID to the data associated with the data write operation. The data block is programmed to a particular logical address within SLC segment 144, and the physical address and the order ID are written to FTL table 132 in an entry associated with the logical address.

In keeping with the understanding that the most recently programmed data to an SSD has a higher likelihood of being read back from the SSD than earlier programmed data, it has been further understood that the most recently read data from the SSD has a higher likelihood of being reread back from the SSD than earlier programmed data. As such, order generator 134 further operates to update the ascribed chronological ordering of the data read from SSD 12, and to record the updated order (the reordered order ID) to the data within FTL table 132. Thus FIG. 1 further illustrates a data read operation from SSD 120 to host system 120. Order ID generator 134 receives the read operation and ascribes the reordered order ID to the data associated with the read operation. The data block is provided to host system 110, and the reordered order ID is written to FTL table 132 in the entry associated with the logical address from which the data read operation was retrieved.

A data read operation may be directed to a data block that is stored in either QLC segment 142 or SLC segment 144. Typically when the data read operation is directed to a data block that is stored in QLC segment 142, the data block will be moved to SLC segment 144, in keeping with the notion of maintaining the SLC segment as a fast cache memory. In this case, the physical address of the data block will change from a physical address within QLC segment 142 to a physical address within SLC segment 144. Further, the logical address associated with the data read operation will be written along with the reordered order ID to the entry within FTL table 132 associated with the logical address within SLC segment 144 to which the data block moved, and the entry within the FTL table associated with the physical address within QLC segment 142 will be invalidated.

Finally, SSD controller 130 operates to evict the least recently used data blocks from SLC segment 144, and to migrate the least recently used data blocks to QLC segment 142 and to update the associated entries in FTL table 132, as needed or desired. For example, SSD controller 130 may operate to determine whether or not a storage utilization threshold for SLC segment 144 is exceeded. When the storage utilization for SLC segment 144 is below the storage utilization threshold, SSD controller 130 may forego any eviction activity of data blocks from SLC segment 144. However, when the storage utilization for SLC segment 144 is above the storage utilization threshold, SSD controller 130 may begin the eviction activity of data blocks from SLC segment 144 based upon the order ID information associated with the data blocks stored within the SLC segment. In particular, SSD controller 130 may perform the eviction activity when SSD 120 is not otherwise active in servicing data write operations or data read operations from host system 110.

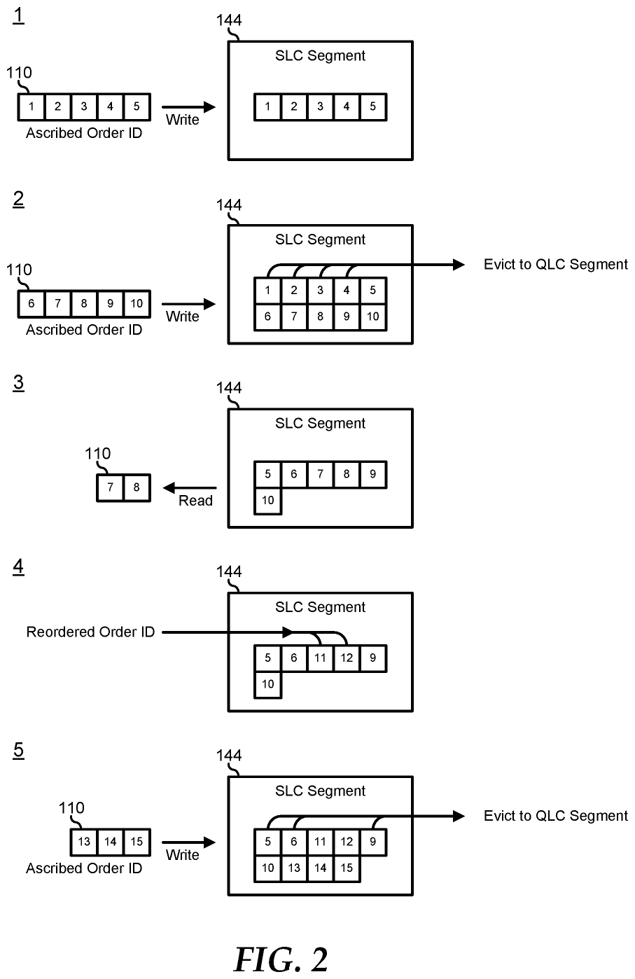

FIG. 2 illustrates a method of providing a data migration scheme using transaction order for faster reads in SSD 120. At a first time (1), SSD 120 receives five (5) data block writes, and order ID generator 134 ascribes a sequence of order IDs (that is, 1-5) to the associated data blocks. The data blocks are written to SLC segment 144, and the associated entries in FTL table 132 are written with the logical addresses and order IDs. At a second time (2), SSD 120 receives five (5) additional data block writes, order ID generator 134 ascribes a sequence of order IDs (that is, 6-10) to the associated data blocks, the data blocks are written to SLC segment 144, and the associated entries in FTL table 132 are written with the logical addresses and order IDs. Then when SSD 120 is not otherwise active in servicing data write operations or data read operations from host system 110, the SSD operates to evict the least recently used data blocks (that is, the data blocks associated with order IDs 1-4) to QLC segment 142.

At a third time (3), receives data block reads for the data blocks associated with order IDs 7 and 8, and at a fourth time (4), order ID generator 134 ascribes reordered order IDs (that is, 11 and 12) to the associated data blocks, and the associated entries in FTL table 132 are written with the reordered order IDs. At a fifth time (5), SSD 120 receives three (3) additional data block writes, order ID generator 134 ascribes a sequence of order IDs (that is, 13-15) to the associated data blocks, the data blocks are written to SLC segment 144, and the associated entries in FTL table 132 are written with the logical addresses and order IDs. Then when SSD 120 is not otherwise active in servicing data write operations or data read operations from host system 110, the SSD operates to evict the least recently used data blocks (that is, the data blocks associated with order IDs 5, 6, and 9) to QLC segment 142.

It has been determined by the inventors of the current disclosure that the read performance of SSDs that utilize the typical caching policy and algorithm decreases as the utilization of the total storage capacity of the SSD increases. However, utilizing the caching policy and algorithm based upon the ordering of the data programmed to the SSD, as described herein, suffers far less performance degradation as the utilization of the total storage capacity increases. Note that where workloads instantiated on host system 110 are more write intensive, SSD controller 130 may operate to monitor the write activity provided by the caching scheme and algorithm as described above, and can determine whether or not the continued use of the caching scheme and algorithm are suitable for maintaining the longevity of SSD 120. When SSD controller 130 determines that the longevity of SSD 120 is at risk, the SSD controller can operate to switch the caching scheme and algorithm to ensure adequate longevity of the SSD. For example, SSD controller 130 can switch to a caching scheme and algorithm based upon a measurement of the total bytes written (TBW), or to another caching scheme and algorithm, as needed or desired.

FIG. 3 illustrates a generalized embodiment of an information handling system 300 similar to information handling system 300. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 300 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 300 can include processing resources for executing machine-executable code, such as a central processing unit (CPU), a programmable logic array (PLA), an embedded device such as a System-on-a-Chip (SoC), or other control logic hardware. Information handling system 300 can also include one or more computer-readable medium for storing machine-executable code, such as software or data. Additional components of information handling system 300 can include one or more storage devices that can store machine-executable code, one or more communications ports for communicating with external devices, and various input and output (I/O) devices, such as a keyboard, a mouse, and a video display. Information handling system 300 can also include one or more buses operable to transmit information between the various hardware components.

Information handling system 300 can include devices or modules that embody one or more of the devices or modules described below, and operates to perform one or more of the methods described below. Information handling system 300 includes a processors 302 and 304, an input/output (I/O) interface 310, memories 320 and 325, a graphics interface 330, a basic input and output system/universal extensible firmware interface (BIOS/UEFI) module 340, a disk controller 350, a hard disk drive (HDD) 354, an optical disk drive (ODD) 356, a disk emulator 360 connected to an external solid state drive (SSD) 362, an I/O bridge 370, one or more add-on resources 374, a trusted platform module (TPM) 376, a network interface 380, a management device 390, and a power supply 395. Processors 302 and 304, I/O interface 310, memory 320, graphics interface 330, BIOS/UEFI module 340, disk controller 350, HDD 354, ODD 356, disk emulator 360, SSD 362, I/O bridge 370, add-on resources 374, TPM 376, and network interface 380 operate together to provide a host environment of information handling system 300 that operates to provide the data processing functionality of the information handling system. The host environment operates to execute machine-executable code, including platform BIOS/UEFI code, device firmware, operating system code, applications, programs, and the like, to perform the data processing tasks associated with information handling system 300.

In the host environment, processor 302 is connected to I/O interface 310 via processor interface 306, and processor 304 is connected to the I/O interface via processor interface 308. Memory 320 is connected to processor 302 via a memory interface 322. Memory 325 is connected to processor 304 via a memory interface 327. Graphics interface 330 is connected to I/O interface 310 via a graphics interface 332, and provides a video display output 336 to a video display 334. In a particular embodiment, information handling system 300 includes separate memories that are dedicated to each of processors 302 and 304 via separate memory interfaces. An example of memories 320 and 330 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 340, disk controller 350, and I/O bridge 370 are connected to I/O interface 310 via an I/O channel 312. An example of I/O channel 312 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 310 can also include one or more other I/O interfaces, including an Industry Standard Architecture (ISA) interface, a Small Computer Serial Interface (SCSI) interface, an Inter-Integrated Circuit (I2C) interface, a System Packet Interface (SPI), a Universal Serial Bus (USB), another interface, or a combination thereof. BIOS/UEFI module 340 includes BIOS/UEFI code operable to detect resources within information handling system 300, to provide drivers for the resources, initialize the resources, and access the resources. BIOS/UEFI module 340 includes code that operates to detect resources within information handling system 300, to provide drivers for the resources, to initialize the resources, and to access the resources.

Disk controller 350 includes a disk interface 352 that connects the disk controller to HDD 354, to ODD 356, and to disk emulator 360. An example of disk interface 352 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 360 permits SSD 364 to be connected to information handling system 300 via an external interface 362. An example of external interface 362 includes a USB interface, an IEEE 1394 (Firewire) interface, a proprietary interface, or a combination thereof. Alternatively, solid-state drive 364 can be disposed within information handling system 300.

I/O bridge 370 includes a peripheral interface 372 that connects the I/O bridge to add-on resource 374, to TPM 376, and to network interface 380. Peripheral interface 372 can be the same type of interface as I/O channel 312, or can be a different type of interface. As such, I/O bridge 370 extends the capacity of I/O channel 312 when peripheral interface 372 and the I/O channel are of the same type, and the I/O bridge translates information from a format suitable to the I/O channel to a format suitable to the peripheral channel 372 when they are of a different type. Add-on resource 374 can include a data storage system, an additional graphics interface, a network interface card (NIC), a sound/video processing card, another add-on resource, or a combination thereof. Add-on resource 374 can be on a main circuit board, on separate circuit board or add-in card disposed within information handling system 300, a device that is external to the information handling system, or a combination thereof.

Network interface 380 represents a NIC disposed within information handling system 300, on a main circuit board of the information handling system, integrated onto another component such as I/O interface 310, in another suitable location, or a combination thereof. Network interface device 380 includes network channels 382 and 384 that provide interfaces to devices that are external to information handling system 300. In a particular embodiment, network channels 382 and 384 are of a different type than peripheral channel 372 and network interface 380 translates information from a format suitable to the peripheral channel to a format suitable to external devices. An example of network channels 382 and 384 includes InfiniBand channels, Fibre Channel channels, Gigabit Ethernet channels, proprietary channel architectures, or a combination thereof. Network channels 382 and 384 can be connected to external network resources (not illustrated). The network resource can include another information handling system, a data storage system, another network, a grid management system, another suitable resource, or a combination thereof.

Management device 390 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 300. In particular, management device 390 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 300, such as system cooling fans and power supplies. Management device 390 can include a network connection to an external management system, and the management device can communicate with the management system to report status information for information handling system 300, to receive BIOS/UEFI or system firmware updates, or to perform other task for managing and controlling the operation of information handling system 300. Management device 390 can operate off of a separate power plane from the components of the host environment so that the management device receives power to manage information handling system 300 when the information handling system is otherwise shut down. An example of management device 390 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 390 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

1. An information handling system, comprising:
a host system; and
a solid state drive (SSD) including a memory array having a plurality of memory cells and a controller, wherein the memory array includes a first portion of the memory cells configured to store one bit per cell, and a second portion of the memory cells configured to store more than one bit per cell, wherein the controller is configured to utilize the first portion as a cache for the second portion, wherein the controller utilizes a caching policy based upon a plurality of unique order identifiers, each order identifier being associated with a particular data block stored in the first portion, and wherein each order identification is determined as a next sequential number based upon a chronological order in which the associated data is accessed in the first portion.

2. The information handling system of claim 1, wherein, for a first data write transaction from the host system to the SSD, the controller ascribes a first order identifier to first data of the first data write transaction, the first order identifier being associated with the chronological order in which the first data write transaction was received.

3. The information handling system of claim 2, wherein, for a second data write transaction from the host system to the SSD, the controller further ascribes a second order identifier to second data of the second data write transaction, the second order identifier being associated with a next in the chronological order in which the second data write transaction was received.

4. The information handling system of claim 3, wherein in managing data stored in the first portion, the controller operates to determine that the second order identifier is higher than the first order identifier, and to evict the first data to the second portion in response to determining that the second order identifier is higher than the first order identifier.

5. The information handling system of claim 2, wherein, for a data read transaction from the host system to the SSD, the controller further ascribes a second order identifier to second data of the data read transaction, the second order identifier being associated with a next in the chronological order in which the data read transaction was received.

6. The information handling system of claim 5, wherein in managing data stored in the first portion, the controller operates to determine that the second order identifier is higher than the first order identifier, and to evict the first data to the second portion in response to determining that the second order identifier is higher than the first order identifier.

7. The information handling system of claim 2, wherein the controller operates store the first data to a physical address within the first portion, to determine a logical address associated with the first data write transaction, and to store the logical address and the first order identifier to a translation table.

8. The information handling system of claim 7, wherein the controller is further configured to store the logical address and the first order identifier to an entry of the translation table that is associated with the physical address.

9. The information handling system of claim 7, wherein the controller includes the translation table.

10. The information handling system of claim 7, wherein the host system includes the translation table.

11. A method comprising:
providing, on a solid state drive (SSD), a memory array having a plurality of memory cells, wherein the memory array includes a first portion of the memory cells configured to store one bit per cell, and a second portion of the memory cells configured to store more than one bit per cell; and
providing, on the SSD, a controller configured to utilize a caching policy based upon a plurality of unique order identifiers, each order identifier being associated with a particular data block stored in the first portion, wherein each order identification is determined as a next sequential number based upon a chronological order in which the associated data is accessed in the first portion.

12. The method of claim 11 wherein, for a first data write transaction from the host system to the SSD, the method further comprises ascribing, by the controller, a first order identifier to first data of the first data write transaction, the first order identifier being associated with the chronological order in which the first data write transaction was received.

13. The method of claim 12 wherein, for a second data write transaction from the host system to the SSD, the method further comprises ascribing, by the controller, a second order identifier to second data of the second data write transaction, the second order identifier being associated with a next in the chronological order in which the second data write transaction was received.

14. The method of claim 13 wherein, in managing data stored in the first portion, the method further comprises:
determining, by the controller, that the second order identifier is higher than the first order identifier; and
evicting the first data to the second portion in response to determining that the second order identifier is higher than the first order identifier.

15. The method of claim 12 wherein, for a data read transaction from the host system to the SSD, the method further comprises ascribing, by the controller, a second order identifier to second data of the data read transaction, the second order identifier being associated with a next in the chronological order in which the data read transaction was received.

16. The method of claim 15, wherein in managing data stored in the first portion, the method further comprises:
determining, by the controller, that the second order identifier is higher than the first order identifier; and
evicting the first data to the second portion in response to determining that the second order identifier is higher than the first order identifier.

17. The method of claim 12, further comprising:
storing, by the controller, the first data to a physical address within the first portion;
determining a logical address associated with the first data write transaction; and
storing the logical address and the first order identifier to a translation table.

18. The method of claim 17, further comprising storing the logical address and the first order identifier to an entry of the translation table that is associated with the physical address.

19. The method of claim 17, wherein the controller includes the translation table.

20. A solid state drive, comprising:
a memory array having a plurality of memory cell, the memory array including a first portion of the memory cells configured to store one bit per cell, and a second portion of the memory cells configured to store more than one bit per cell; and
a controller configured to utilize the first portion as a cache for the second portion, wherein the controller utilizes a caching policy based upon a plurality of unique order identifiers, each order identifier being associated with a particular data block stored in the first portion, and wherein each order identification is determined as a next sequential number based upon a chronological order in which the associated data is accessed in the first portion.
